(19) United States
(12) Patent Application Publication
(10) Pub. No.: US 2019/0181095 A1
(43) Pub. Date: Jun. 13, 2019

(54) EMI SHIELDING FOR DISCRETE INTEGRATED CIRCUIT PACKAGES

(71) Applicant: Unisem (M) Berhad, Ipoh (MY)

(72) Inventors: Kwai Hong Wong, Ipoh (MY); Wai Kuen Lam, Ipoh (MY)

(73) Assignee: Unisem (M) Berhad, Ipoh (MY)

(21) Appl. No.: 15/836,262

(22) Filed: Dec. 8, 2017

(51) Int. Cl. H01L 23/552; H01L 23/28; H01L 23/495

(52) U.S. Cl. CPC H01L 23/552; H01L 23/49575; H01L 23/28

(57) ABSTRACT

A method is disclosed for manufacturing a discrete package for housing at least one integrated circuit die with electromagnetic interference shielding. The method may utilize a lead frame with a central die paddle and outwardly extending leads. The die paddle may have a top surface and an opposing bottom surface. The method may also have at least one integrated circuit die with a top surface and an opposing bottom surface. The integrated circuit die may be attached to the top surface of the die paddle. At least one conductive material bond may be established between the lead frame and the integrated circuit die. A dielectric material over mold may encapsulate the integrated circuit die and lead frame. A second dielectric material over mold may encapsulate the integrated circuit die and the lead frame. Further, a conductive coating may encapsulate the top and side surfaces of the package.

### BACKGROUND

Integrated Circuit (IC) device manufacturers protect their IC devices with Electromagnetic Interference (EMI) shielding. EMI degrades electronic device performance. Electromagnetic interference may modify an IC's performance through electromagnetic induction, electrostatic coupling, conduction, or induction. Small devices, such as tablets and cellphones, are particularly vulnerable to EMI because of their compactness and proximity to wireless signals. Because of this, EMI shielding is increasingly important for electronic devices. Nearly any connected wire may become an antenna for an IC. Unshielded conductive materials are generally capable of receiving and transmitting electromagnetic signals regardless of the manufacturer's intent. Manufacturers use several existing packaging methods to apply EMI shielding to IC packages. Examples of typical packaging methods include metal sputtering, conductive spray coating, ink printing, and compartment shielding. Most current EMI shielding techniques are intended to shield laminate substrate packages such as Ball Grid Array (BGA) or Land Grid Array (LGA) packages. Typical EMI shielding techniques, such as these, cover multiple IC packages in an array and do not shield discrete IC packages.

In some cases, a manufacturer may only be able to provide adequate EMI shielding for an application if it uses a discrete IC package EMI shielding method. Some sensitive portions of IC packages may not have adequate shielding after a typical EMI shielding process is complete. A typical method of EMI shielding involves assembling an integrated circuit module that includes several integrated circuit packages and separating the module into discrete components. In a traditional grid array or modular shielding process, the separated IC leads typically remain exposed. An integrated circuit device manufacturer may also waste space on a module board when using a modular shielding method because excess space on a circuit board is covered by EMI shielding material that otherwise would have contained circuits. Typically, an IC must retain some exposed portions of its leads so that the IC may connect to other electrical components. But, the package is consequently exposed to EMI, which degrades the performance of the system that it belongs to.

There is a need for an EMI shielding method that allows a manufacturer to apply EMI shielding to a discrete IC package, such that the manufacturer may shield the sides of discrete IC the package leads. The discrete IC package must also retain the ability to connect with other electronic devices on a printed circuit board after it has been EMI shielded.

U.S. Patent Application Publication No. 2007/0075409 A1 by Letterman et al., titled “Method of forming a molded array package device having an exposed tab and structure,” discloses a typical IC EMI shielding process, and is incorporated by reference herein in its entirety. Electronic chips are connected to specific leads on a lead frame. The process molds an array lead frame and leaves portions of the leads exposed. After the molding portion of the process is completed, then packages are separated. The separated packages maintain the exposed leads that were preserved during the molding process. Alternative embodiments of this application do not incorporate leads, but instead incorporate exposed tabs to connect an IC to other components. The tabs are typically exposed to EMI in the same way that the alternative leads may be exposed as described above.

There are alternative methods of EMI shielding such as the method that is disclosed in U.S. Pat. No. 8,053,872 B1, by Swan et al., titled “Integrated shield for a no-lead semiconductor device package,” which is incorporated by reference herein in its entirety. A semiconductor array contains multiple rows of contact pads along any side. Die pads are connected to a die attach pad and connected with wire bonds. After internal connections are established, an over mold body is formed over the die, die attach pad, wire bonds, and an inner row of attach pads. The over mold may encapsulate all but an outer row of exposed leads that are exposed to connect the IC array to additional components. The IC array is then separated into individual package structures. According to the typical shielding process, as disclosed here, the package leads are not over molded and they are not covered by EMI shielding. As disclosed here, typically there is at least some exposed portion of an integrated circuit package that is not EMI shielded. The EMI shielding processes usually must preserve this unshielded portion of the IC package so that the package can connect to other electrical components.

### SUMMARY OF THE DISCLOSURE

In accordance with an aspect of the disclosure, there is provided a method for the manufacture of a discrete package for housing one or more integrated circuit die and providing electromagnetic interference shielding. A lead frame is provided, having a centrally disposed die paddle and outwardly extending leads, the die paddle having a top surface and an opposing bottom surface. At least one integrated circuit die is provided having a top surface and an opposing bottom surface. At least one integrated circuit die is attached to the top surface of the die paddle and at least one wire bond is created between the lead frame and the at least one integrated circuit die. A dielectric material is first over molded, encapsulating the at least one integrated circuit die and the lead frame on a top and on a set of sides. The dielectric material is singulated with a first singulation, wherein a width of the singulation is effective to retain a layer of over mold on the sides of the lead frame. The dielectric material is second over molded on a top and on a set of sides. The dielectric material is singulated with a second singulation, wherein a width of the second singulation is less than the width of the first singulation. A conductive coating is applied to the package top surface and package side surfaces.

### BRIEF DESCRIPTION OF THE DRAWINGS

FIG. 1 schematically illustrates, in cross-section view, a semiconductor lead frame that includes a tie-bar a lead and a paddle.

FIG. 2 illustrates two integrated circuit die connected to the lead frame illustrated in FIG. 1.

FIG. 3 and FIG. 4 illustrate examples of connective material bonds among integrated circuit die and the semiconductor lead frame illustrated in FIG. 1.

FIG. 5 illustrates, in cross-section view, multiple integrated circuit packages connected by a wire bond. FIG. 5 further illustrates an example of a saw street where a package saw singulation may operate.

FIG. 6 illustrates the integrated circuit packages shown in FIG. 5 where a dielectric material over mold is applied the integrated circuit packages.

FIG. 7 illustrates the over molded integrated circuit packages of FIG. 6 after singulation.

FIG. 8 illustrates an over molded and singulated integrated circuit package as shown in

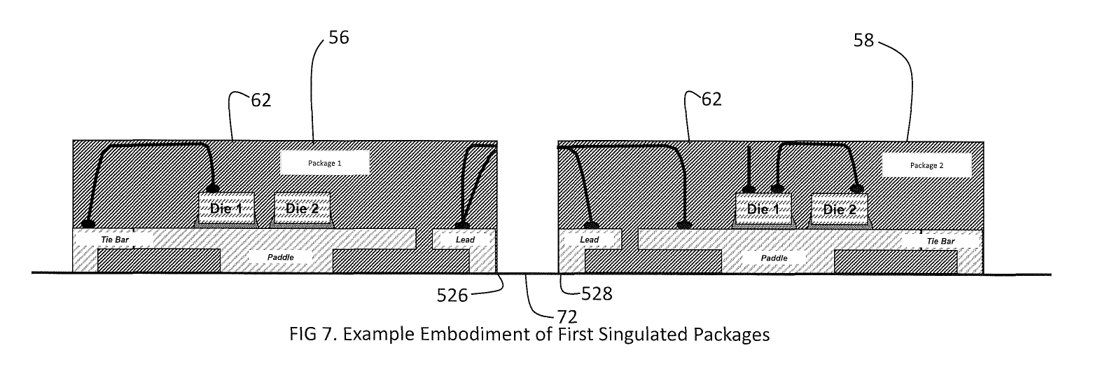

FIG. 7 that has received a second dielectric material over mold.

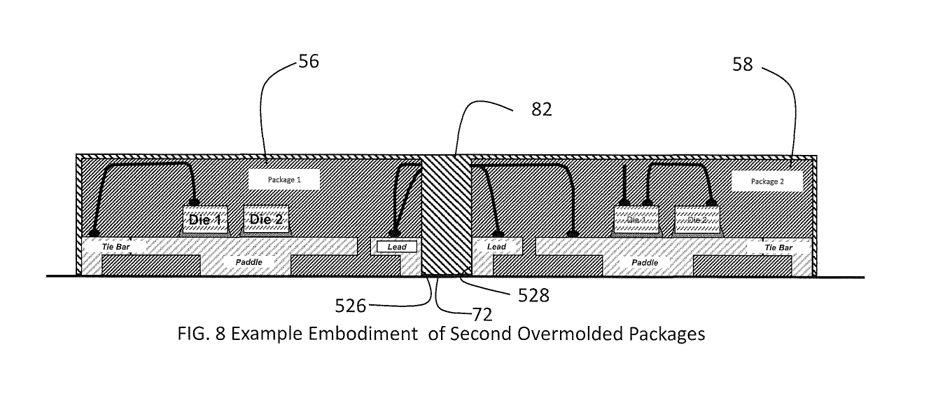

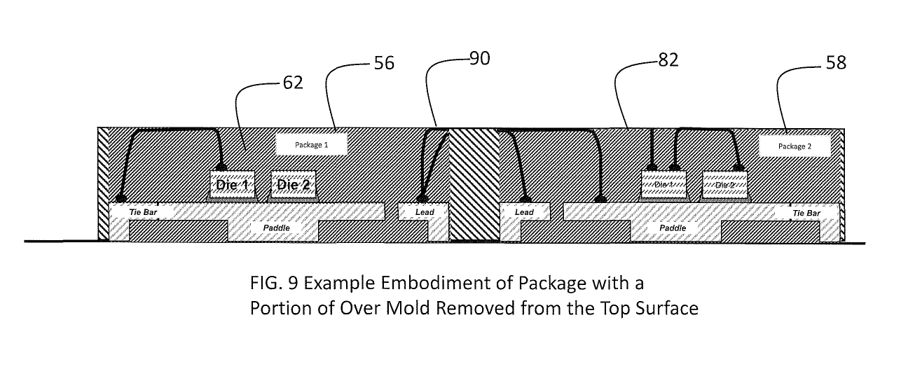

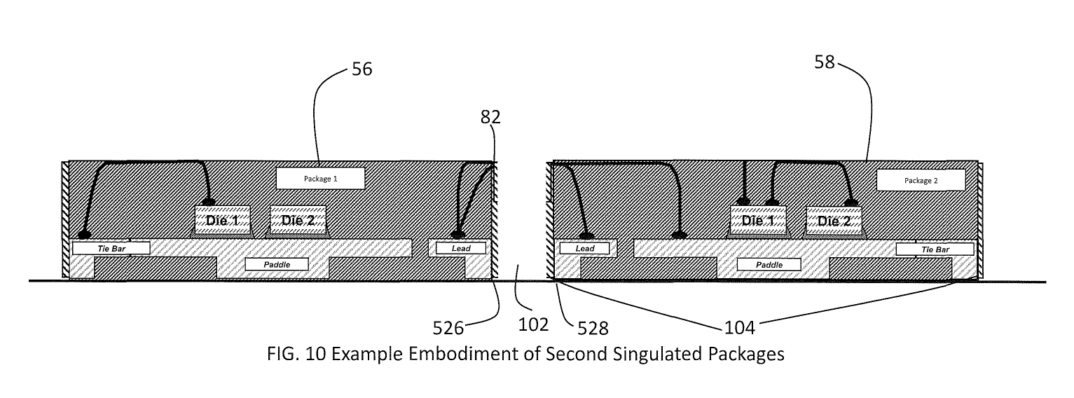

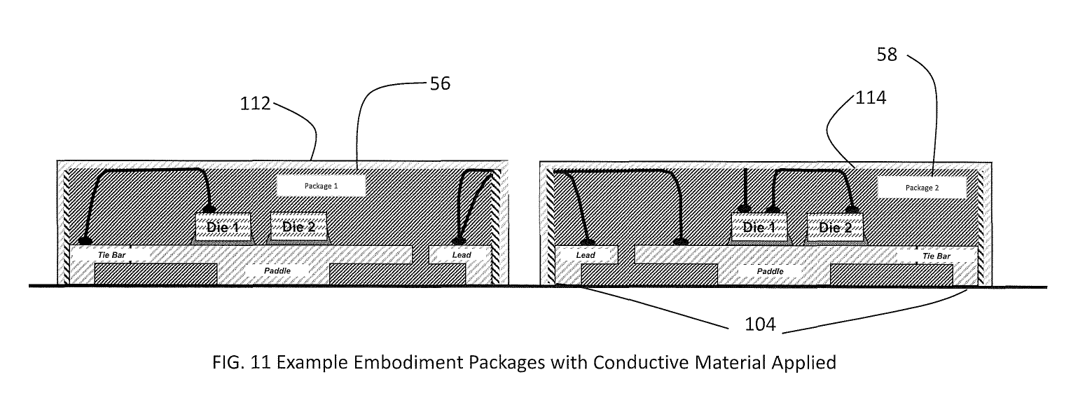

FIG. 9 illustrates the integrated circuit packages shown in FIG. 8 with connections exposed by laser or mechanical abrasion.

FIG. 10 illustrates the integrated circuit packages shown in FIG. 9 with a second package saw singulation.

FIG. 11 illustrates the integrated circuit packages shown in FIG. 10 with a conductive material applied to the outside of two integrated circuit package.

### DETAILED DESCRIPTION

Methods for the manufacture of a discrete package for housing one or more integrated circuit die and providing electromagnetic interference shielding are described below.

As used herein, orientation terms such as “top,” “bottom,” “side,” “top surface,” “bottom surface,” “side surface,” and the like are intended to indicate relative position within the geometry discussed. These terms are not intended to indicate an absolute direction or orientation. The Willis show the relative orientation between discussed components in example embodiments. Example: the “bottom surface” of a lead frame may actually be situated above an integrated circuit die to which it is connected.

As used herein, the term “wire bond” is intended to indicate any type of conductive material electrical connection. The term “wire bond” is not intended to limit an embodiment to a particular wire form. Examples of wire bonds may include straight wire, flat loop wire, and square loop wire formations.

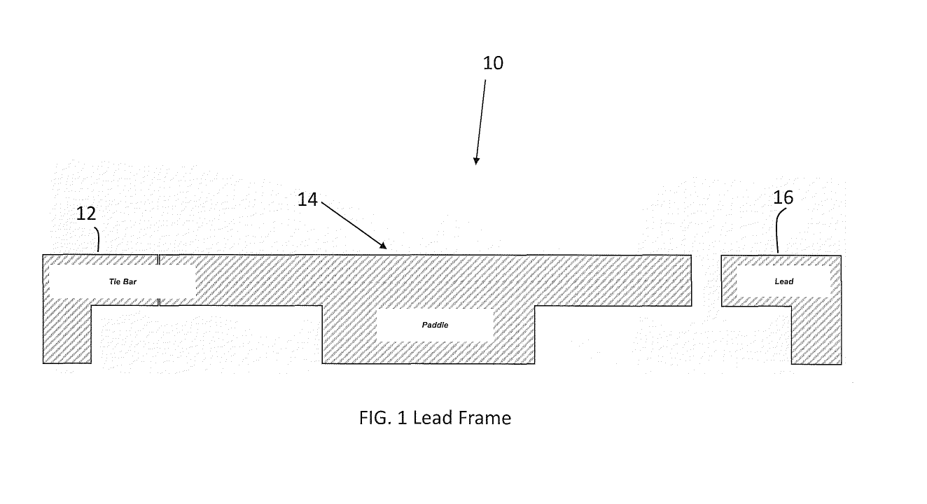

FIG. 1 illustrates, in a cross-section, an integrated circuit lead frame 10 and components including a tie bar 12, a die paddle 14, and a plurality of leads 16. The lead frame 10 may be used to connect several integrated circuit packages that may be grouped together or singulated into discrete packages. The die paddle 14 may be centrally disposed in relation to the entire lead frame 10. The leads 16 may be outwardly extending in relation to the entire lead frame 10.

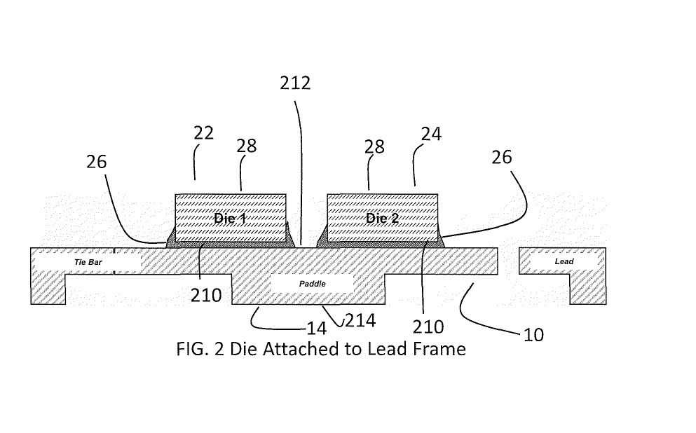

FIG. 2 illustrates a first integrated circuit die 22, and a second integrated circuit die 24, attached to an integrated circuit lead frame 10. Both the first integrated circuit die 22 and the second integrated circuit die 24 are connected to the lead frame paddle 14. The first integrated circuit die 22, and the second integrated circuit die 24 may be connected directly to the lead frame 10 or they may be connected by use of conductive or non-conductive adhesive 26. The first integrated circuit die 22, and the second integrated circuit die 24, may have a top surface 28 and an opposing bottom surface 210. The die paddle 14 may have a top surface 212 and an opposing bottom surface 214. In embodiments, a bottom surface 210 of the first integrated circuit die 22, and the second integrated circuit die 24, may be connected to the top surface 212 of the die paddle 14. Conductive or non-conductive adhesive 26 may be used to attach the first integrated circuit die 22, and the second integrated circuit die 24 to the lead frame 10 die paddle 14.

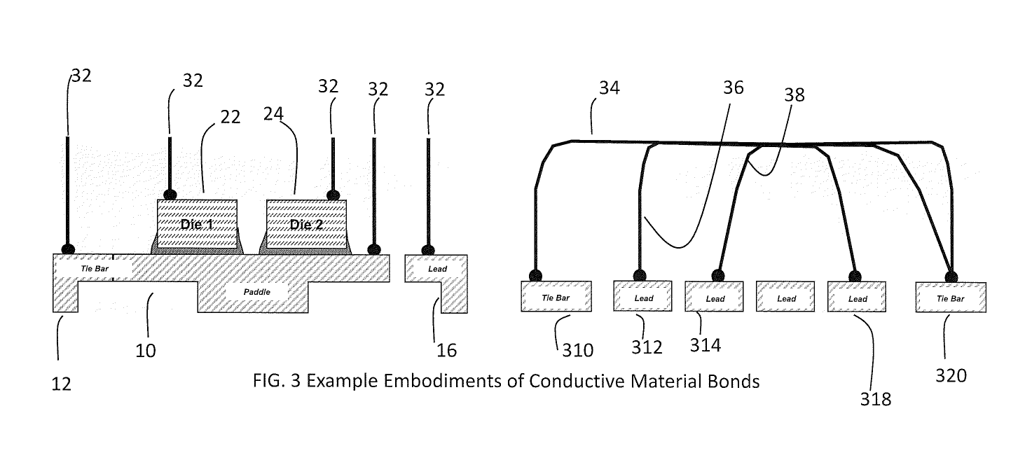

FIG. 3 illustrates several examples of possible configurations for wire bonds with the circuit lead frame 10 and the integrated circuit die 22, 24. There is a wire bond 32 between a tie bar 12 and ground (as also explained in relation to FIG. 9), a lead 16 and ground, a first integrated circuit die 22 and ground, and a second integrated circuit die 24 to ground. There are wire bonds 34 between a tie bar 310 and a second tie bar 320, wire bonds 36 between a lead 312 and a second lead 318, and wire bonds 38 between a lead 314 and a tie bar 320. Some, but not all, possible configurations for wire bonds between a lead frame 10 and integrated circuit die 22, 24 are shown.

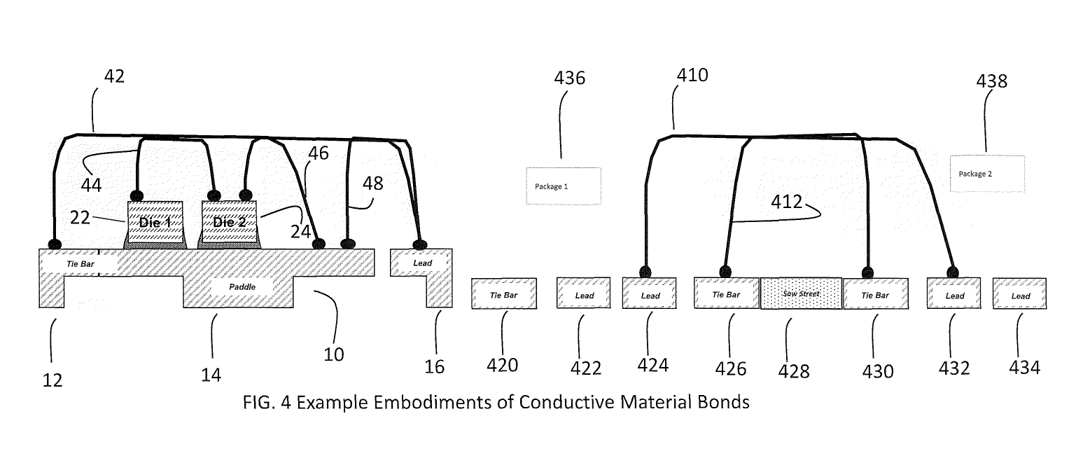

FIG. 4 illustrates several examples of possible configurations for wire bonds among the circuit lead frame 10 and the integrated circuit die 22, 24. There are wire bonds 44 between the first die 22 and the second die 24, wire bonds 46 between the second die 24 and the die paddle 14, wire bonds 48 between the die paddle 14 and the lead 16, wire bonds 42 between the tie bar 12 and the lead 16, and wire bonds 48 between a die paddle 14 and a lead 16. Further, there are wire bonds between two integrated circuit packages. As discussed later in the description, a saw street 428 may define a location where a package saw may be executed to separate parts of an integrated circuit package. In embodiments, the saw street 428 may form two separate packages: a “Package 1” 436 and a “Package 2” 438. “Package 1” 436 is configured where a lead frame's components are located in succession from a first side to a second side, where the successive components in order are a first tie bar 420, a first lead 422, a second lead 424, and a second tie bar 426. “Package 2” is configured where a lead frame's components are located in succession from a first side to a second side, where the successive components, in order, are a tie bar 430, a first lead 432, and a second lead 434. There is a wire bond 410 between the second lead 424 on the first package 436 and the first lead 432 on the second package 438. There is a wire bond 412 between the second tie bar 426 on the first package 436, and the tie bar 430 on the second package 438. Further, there is a saw street 428, which may also be referred to as a scribe line or a spacing. The saw street 428 is located between the second tie bar 426 in the first package 436, and the tie bar 430 in the second package 438 that are connected by a wire bond 412. In embodiments, a saw street 428 may exist to denote a location where a package saw may be executed.

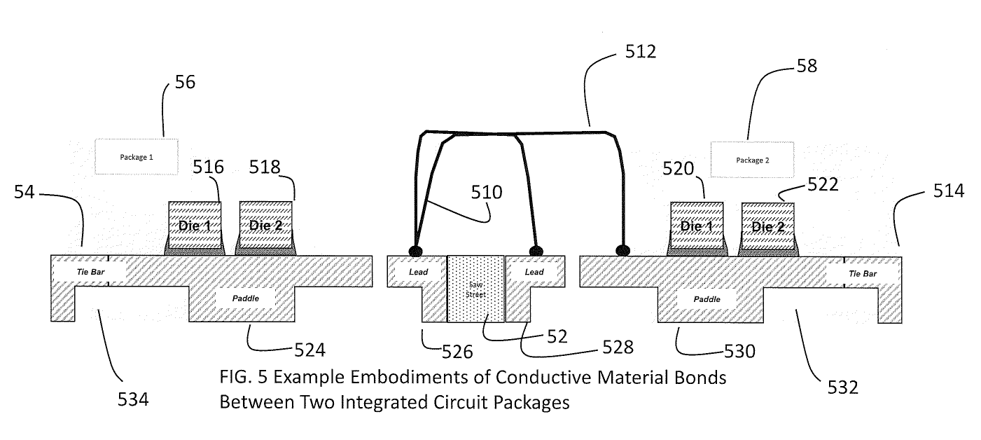

FIG. 5 illustrates a first integrated circuit package “Package 1” 56 and a second integrated circuit package “Package 2.” 58 “Package 1” 56 contains a lead frame 534, a first die 516 and a second die 518. “Package 2” 58 contains a lead frame 532 a first die 520 and a second die 522. “Package 1” 56 components are adjacent to each other from a first side to a second side in succession where the components are a tie bar 54, a paddle 524, and a lead 526, as shown in FIG. 2. “Package 2” 58 components are adjacent to each other from a first side to a second side in succession where the components are a lead 528, a paddle 530, and a tie bar 514 in a reverse configuration of what is shown in FIG. 2. The “Package 1” lead 526 and the “Package 2” lead 528 are connected by a wire bond 510. The “Package 1” lead 526 and the “Package 2” paddle 530 are connected by a wire bond 512. FIG. 5 further shows a saw street 52 positioned between the “Package 1” 56 lead 526 and the “Package 2” 58 lead 528.

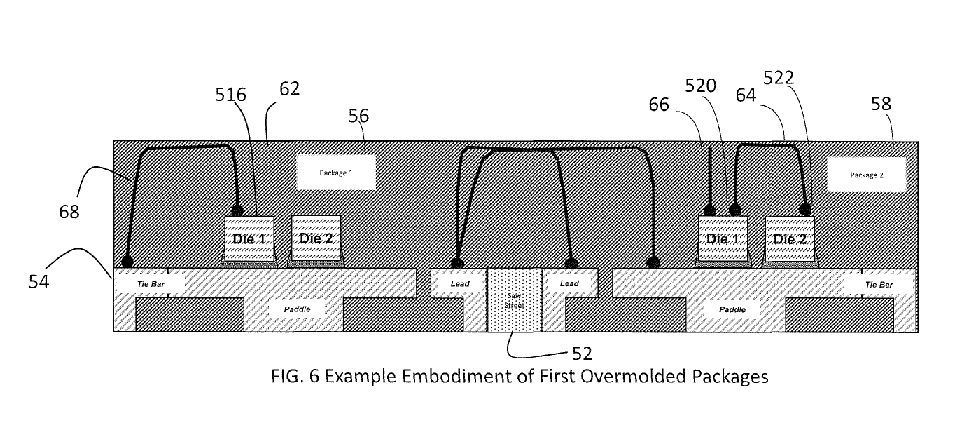

FIG. 6 illustrates, “Package 1” 56 and “Package 2” 58 as shown in FIG. 5 with a first over mold where the first over mold is a dielectric material over mold 62 and additional wire bonds 68 between the “Package 1” 56 tie bar 54 and the “Package 1” first die 516. Further, there is a wire bond 66 between “Package 2” first die 520, and a wire bond 64 between “Package 2” first die 520, and “Package 2” second die 522. The dielectric material over mold 62 encapsulates “Package 1” 56 and “Package 2” 58. In embodiments, the dielectric material over mold 62 covers all outer surfaces of “Package 1” 56 and “Package 2” 58. In embodiments, the dielectric material over mold 62 may be any material that has dielectric properties. In example embodiments, the dielectric material over mold 62 may be made of a standard integrated circuit molding compound. A standard integrated circuit molding compound may contain an epoxy resin sufficient to shield an integrated circuit from EMI.

FIG. 7 illustrates the dielectric material over molded 62 “Package 1,” 56 and “Package 2,” 58 as shown in FIG. 6, after a first singulation 72. In embodiments, dielectric material over mold 62 that encapsulates multiple integrated circuit packages may be singulated with a first singulation 72. In embodiments, dielectric material over mold 62 may be singulated at a saw street 52 location, as shown in FIG. 6. In embodiments, the singulation width may be such that the first singulation 72 leaves a layer of first dielectric material over mold 62 covering the leads 526, 528, in “Package 1” 56 and “Package 2” 58 respectively. The width of the first singulation 72 may also be a diameter. In embodiments, the width of the first singulation 72 may be from 0.20 mm to 0.40 mm and preferably nominally 0.30 mm. In embodiments, the layer of dielectric material over mold 62 covering the leads 526, 528 is sufficiently thick to cover the leads 526, 528 with a layer of dielectric material over mold 62 that isolates the leads 526, 528 from outside electromagnetic interference. In embodiments, a sufficiently thick layer of first dielectric material over mold 62 to isolate the leads 526, 528 may be the Standard SLP thickness effective to isolate the leads 526, 528. In embodiments, the dielectric material over mold 62 covers the leads 526, 528 in their entirety, such that there is no exposed surface on the leads 526, 528.

FIG. 8 illustrates integrated circuit packages 56, 58, as shown in FIG. 7, with a second over mold where the second over mold is a second dielectric material over mold 82. Note that the second dielectric material over mold 82 encapsulates “Package 1” 56 and “Package 2” 58 and the second dielectric material over mold 82 further fills a singulated space 72. In embodiments, the second dielectric material over mold 82 encapsulates the leads 526, 528. The second dielectric material over mold 82 may be made of a standard integrated circuit molding compound. A standard molding compound may contain an epoxy resin sufficient to shield an integrated circuit from EMI. The thickness of the layer of second dielectric material over mold 82 may vary according to the size of the package that it is applied to. An example embodiment second dielectric material over mold 82 may have a thickness of 63.00 μm for a package size less than or equal to 5 mm×5 mm.

FIG. 9 illustrates the set of dielectric material over molded 62, 82 packages shown in FIG. 8 where a portion of the second dielectric material over mold, 82 or first dielectric material over mold 62 and second dielectric material over mold 82 may be removed from the top surface 90 of “Package 1” 56 and “Package 2” 58 by mechanical abrasion or laser etching. In embodiments, mechanical abrasion may be in the form of grinding, buffing, chemical reaction, or any other form of mechanical abrasion.

FIG. 10 illustrates the set of dielectric material over molded 62 packages as shown in FIG. 9 where the second dielectric material over mold 82 has been singulated with a second singulation 102. The width of the second singulation 102 is less than the width of the first singulation 72, shown in FIG. 7, such that the second singulation 102 leaves a layer 104 of the second dielectric material over mold 82 on a set of sides 104 of “Package 1” 56 and package 2″ 58. In embodiments, the second singulation 102 may be from 0.10 mm to 0.30 mm and preferably nominally 0.20 mm. “Package 1,” 56 and “Package, 2” 58 may have at least four sides 104 that remain covered by the second dielectric material over mold 104 after the second singulation 102. In embodiments, the set of sides of “Package 1” 56 and “Package 2” 58 may include the locations of the leads 526, 528.

FIG. 11 illustrates the set of dielectric material over molded packages, as shown in FIG. 10, with a conductive material 112, applied to the top surfaces 114 and side surfaces 104 of “Package 1” 56 and “Package 2” 58. The conductive material is applied such that the top surfaces 114 and side surfaces 104 of “Package 1” 56 and “Package 2” 58 are covered with the conductive material 112. The conductive material 112 may also be referred to as a conductive coating. This process, as illustrated in the present embodiment, may be referred to as metal shielding or conductive material coating. In some embodiments, metal shielding may be accomplished by sputtering, coating, electroplating, electro-less plating, printing, or any other method of metal shielding. In some embodiments the conductive material 112 may be made of a single electrically conductive material or a combination of electrically conductive materials such as Copper and Titanium or Copper and Nickel.

1. A method for the manufacture of a discrete package for housing one or more integrated circuit die and providing electromagnetic interference shielding, comprising the steps:
providing a lead frame having a centrally disposed die paddle and outwardly extending leads, the die paddle having a top surface and an opposing bottom surface;
providing at least one integrated circuit die having a top surface and an opposing bottom surface;
attaching the at least one integrated circuit die to the top surface of the die paddle;
creating at least one conductive material bond between the lead frame and the at least one integrated circuit die;
first over molding a dielectric material, encapsulating the at least one integrated circuit die and the lead frame on a top and on a set of sides;
first singulating the dielectric material wherein a width of the first singulation is effective to retain a layer of first over mold on the sides of the lead frame;
second over molding the dielectric material on a top and on a set of sides;
second singulating the dielectric material, wherein a width of the second singulation is less than the width of the first singulation; and
applying a conductive coating to the package top surface and package side surfaces.

2. The method for the manufacture of a discrete package for housing one or more integrated circuit die and providing electromagnetic interference shielding of claim 1 wherein the first over mold is to a thickness effective to cover the outwardly extending leads in their entirety.

3. The method for the manufacture of a discrete package for housing one or more integrated circuit die and providing electromagnetic interference shielding of claim 2 wherein the width of the first singulation is 0.30 mm.

4. The method for the manufacture of a discrete package for housing one or more integrated circuit die and providing electromagnetic interference shielding of claim 3 wherein a layer of the second over mold is to a thickness effective to encapsulate the layer of the first over mold.

5. The method for the manufacture of a discrete package for housing one or more integrated circuit die and providing electromagnetic interference shielding of claim 4 wherein the width of the second singulation is effective to retain the layer of the second over mold on the set of sides of the lead frame.

6. The method for the manufacture of a discrete package for housing one or more integrated circuit die and providing electromagnetic interference shielding of claim 5 wherein the second singulation is applied at a width of at least 0.20 mm.

7. The method for the manufacture of a discrete package for housing one or more integrated circuit die and providing electromagnetic interference shielding of claim 6 wherein the second over mold is applied with a thickness of at least 63.00 μm.

8. The method for the manufacture of a discrete package for housing one or more integrated circuit die and providing electromagnetic interference shielding of claim 7 wherein the layer of the second over mold fills a singulated space created from the first singulation.

9. The method for the manufacture of a discrete package for housing one or more integrated circuit die and providing electromagnetic interference shielding of claim 8 wherein the layer of the second over mold is applied such that the layer of the first over mold is between the second over mold and the outwardly extending leads on the set of sides.

10. The method for the manufacture of a discrete package for housing one or more integrated circuit die and providing electromagnetic interference shielding of claim 9 wherein an at least one wire connection is exposed by mechanical abrasion.

11. The method for the manufacture of a discrete package for housing one or more integrated circuit die and providing electromagnetic interference shielding of claim 9 wherein an at least one wire connection is exposed by laser etching.

12. The method for the manufacture of a discrete package for housing one or more integrated circuit die and providing electromagnetic interference shielding of claim 9 wherein the conductive coating is applied covering the first coating and the second coating.

13. The method for the manufacture of a discrete package for housing one or more integrated circuit die and providing electromagnetic interference shielding of claim 12 wherein the conductive coating is applied such that it covers at least one wire.

14. A discrete package for housing one or more integrated circuit die with electromagnetic interference shielding, comprising:
a lead frame having a centrally disposed die paddle and outwardly extending leads, the die paddle having a top surface and an opposing bottom surface;
an at least one integrated circuit die having a top surface and an opposing bottom surface;
the at least one integrated circuit die attached to the top surface of the die paddle;
at least one conductive material bond between the lead frame and the at least one integrated circuit die;
a first dielectric material over mold, that encapsulates the at least one integrated circuit die and the lead frame on a top and on a set of sides;
a second dielectric material over mold that encapsulates the at least one integrated circuit die and the lead frame on a top and on a set of sides; and
a conductive material coating encapsulating a package top surface and a set of package side surfaces.

15. The discrete package for housing one or more integrated circuit die with electromagnetic interference shielding, of claim 14 wherein the second dielectric material over mold encapsulates the first dielectric material over mold.

16. The discrete package for housing one or more integrated circuit die with electromagnetic interference shielding, of claim 15 wherein the outwardly extending leads are covered by the first dielectric material over mold with a thickness of 0.20 mm to 0.40 mm.

17. The discrete package for housing one or more integrated circuit die with electromagnetic interference shielding, of claim 16 wherein the outwardly extending leads are covered by the second dielectric material over mold with a thickness of 0.10 mm to 0.30 mm.

18. The discrete package for housing one or more integrated circuit die with electromagnetic interference shielding, of claim 16 wherein an at least one wire connection is exposed to the conductive material coating.

19. The discrete package for housing one or more integrated circuit die with electromagnetic interference shielding, of claim 18 wherein the outwardly extending leads are covered by a layer of first dielectric material over mold, a layer of second dielectric material over mold and the conductive material coating.
